(19) United States
(12) Patent Application Publication
(10) Pub. No.: US 2025/0364875 A1
(43) Pub. Date: Nov. 27, 2025

(54) ELECTRIC MACHINE FOR A MOTOR VEHICLE

(71) Applicant: Brose Fahrzeugteile SE & Co. Kommanditgesellschaft, Würzburg, Würzburg (DE)

(72) Inventors: Steve EBERLEIN, Hallstadt (DE); Vijaykumar JADHAV, Bamberg (DE); Alexander WÖHNER, Martinsheim (DE); Guoqiang YANG, Bamberg (DE)

(21) Appl. No.: 19/214,321

(22) Filed: May 21, 2025

(30) Foreign Application Priority Data
May 21, 2024 (DE) 10 2024 204 663.9

(51) Int. Cl. H02K 11/00; H02K 5/04; H05K 7/14

(52) U.S. Cl. CPC H02K 11/0094; H02K 5/04; H05K 7/1427

(57) ABSTRACT

An electric machine for a motor vehicle includes an electric motor, a metallic motor housing and motor electronics controlling the electric motor. The motor electronics are disposed on the motor housing. The motor electronics have a printed circuit board assembly with a ground guidance bar and with electronic components. A surface of the printed circuit board assembly is covered substantially completely with an electrically non-conductive protective layer except for the ground guidance bar. The ground guidance bar is disposed on the printed circuit board assembly in such a way that, in the event of an electrostatic charge on the motor housing, a discharge arc can form between the motor housing and the ground guidance bar.

### CROSS-REFERENCE TO RELATED APPLICATION

This application claims the priority, under 35 U.S.C. § 119, of German Patent Application DE 10 2024 204 663.9, filed May 21, 2024; the prior application is herewith incorporated by reference in its entirety.

### FIELD AND BACKGROUND OF THE INVENTION

The invention relates to an electric machine for a motor vehicle, including an electric motor and a metallic motor housing as well as motor electronics controlling the electric motor.

In a modern motor vehicle, electric motors are used in a variety of ways as drives for different control elements. Electric motors are used, for example, as window lift, sunroof or seat adjustment drives, as steering drives (EPS, Electrical Power Steering), as radiator fan drives, as transmission actuators, or as brake boosters. Such electric motors must have a relatively high torque or power density and be reliable even at high temperatures.

A brushless electric motor, particularly in the form of an electric (three-phase) machine, usually has a stator that is provided with a field or stator winding, which is disposed coaxially with a rotor with one or more permanent magnets. Both the rotor and the stator are constructed as laminated cores, with stator teeth in intermediate stator slots carrying the coils of the field winding.

In a brushless electric motor, the alternating current used to supply the stator winding is usually generated by an inverter. In smaller electric motors, the inverter, together with associated motor electronics (control electronics), is often housed in an electronics compartment that is integrated into the motor housing.

The motor electronics usually have a printed circuit board assembly (PCBA) which is equipped with electronic components (sensors, controllers, transistors, etc.). In order to center and/or support the printed circuit board assembly in the electronics compartment, the latter can have a recess through the use of which the printed circuit board assembly is, for example, placed in a form-locking manner on an upwardly projecting extension of the motor housing or of the electronics compartment floor.

The metallic motor housing may become electrostatically charged during production and handling of an electric motor that has not yet been installed. That creates the risk of electrostatic discharge (ESD) from the motor housing to the printed circuit board assembly in the form of an electrical arc. Such an arc can damage or completely destroy the electronic components disposed on the printed circuit board assembly before the electric motor is installed in the vehicle.

### SUMMARY OF THE INVENTION

It is accordingly an object of the invention to provide an especially suitable electric machine for a motor vehicle, which overcomes the hereinafore-mentioned disadvantages of the heretofore-known machines of this general type and which achieves a structurally simple and operationally reliable discharge in the event of an electrostatic charge which does not damage the electronic components of the printed circuit board assembly.

With the foregoing and other objects in view there is provided, in accordance with the invention, an electric machine for a motor vehicle, comprising an electric motor and a metallic motor housing as well as motor electronics controlling the electric motor, the motor electronics are disposed on the motor housing, the motor electronics have a printed circuit board assembly with a ground guidance bar and with electronic components, a surface of the printed circuit board assembly is substantially completely covered with an electrically non-conductive protective layer except for the ground guidance bar, the ground guidance bar is disposed on the printed circuit board assembly in such a way that, in the event of an electrostatic charge on the motor housing, an arc discharge can form between the motor housing and the ground guidance bar.

Advantageous embodiments and refinements of the invention constitute the subject matter of the dependent claims.

The electric machine according to the invention is intended for a motor vehicle and is suitable and configured for the same. The electric machine has an electric motor and a metallic motor housing. The electric machine also has motor electronics (control electronics) that control the electric motor.

The motor electronics are embodied in particular as an electronic control unit which is disposed on the motor housing. For example, the motor electronics are located directly at one end of the motor housing. The motor electronics have a printed circuit board (PCB) assembly, i.e., a circuit board or board, which contains electronic components for carrying out the control functions. The printed circuit board assembly also has conductor tracks for electrically contacting and interconnecting these electronic components, as well as a ground guidance bar or ground plane, i.e., an electrically conductor track or surface connected to ground (GND) or mass.

According to the invention, the surface of the printed circuit board assembly is substantially completely covered with an electrically non-conductive or insulating protective layer except for the ground guidance bar. In other words, the surface of the printed circuit board assembly is substantially completely covered with the protective layer, leaving the ground guidance bar exposed (uncoated, uncovered). The term “substantially completely covered or coated” is to be understood here and below in particular to mean that both the printed circuit board and the electronic components and contact points disposed thereon are covered by the protective layer, with, for example, only individual test points of the printed circuit board assembly being exposed. Preferably, all electrically conductive surfaces that do not need to be reached via soldering points, thermal connection, or electrical contact are covered.

Here and in the following, a “test point” is understood to mean in particular a defined contact point on a printed circuit board (PCB) which is intended for electrical testing and diagnosis. This contact point allows electrical measurements to be taken during production or operation to check the functionality and integrity of the motor electronics. The test points are embodied, for example, as metallic surfaces or pins that can be easily contacted with measuring instruments such as oscilloscopes, multimeters, or special test devices.

According to the invention, the exposed ground guidance bar is disposed on the printed circuit board assembly or on the printed circuit board in such a way that, in the event of an electrostatic charge on the motor housing, a discharge arc can form between the motor housing and the ground guidance bar. For example, the distance between the ground conductor and the motor housing is less than 5 mm (millimeters), in particular less than 2 mm. This results in an especially suitable electric machine that is especially safe and reliable in terms of electrostatic discharge.

According to the invention, the electrically non-conductive protective layer increases an impedance for an arc path (discharge path) to the printed circuit board assembly, and the exposed ground guidance bar reduces an impedance of a robust discharge path from the motor housing to ground. This increases the likelihood that an arc will be formed to the ground conductor, thus protecting the electronic components of the printed circuit board assembly. In other words, a reliable discharge path is provided for an electrostatic discharging of the motor housing, while the sensitive electronic components of the motor electronics are protected from arcing at the same time.

The coating of the electronic components with the protective layer further improves the electromagnetic compatibility (EMC) of the motor electronics and hence of the electric machine.

For example, the electric machine is embodied as a brake module, in particular as a so-called “Integrated Power Brake” (IPB), in which the functions of a brake booster and a brake control function are integrated in a single module. Such a brake module thus realizes, for example, the functions of a traditional brake booster, an anti-lock braking system (ABS), and other electronic brake assistance systems.

The electric motor is at least partially disposed in the motor housing. The electric motor has a stator which is stationary or securely fixed to the housing in which a rotor, which is fixed to a motor shaft, is rotatably mounted. The rotor drives, for example, a gear unit which converts the rotational movement of the rotor or the motor shaft into a translational piston movement of a hydraulic unit for generating brake pressure. The motor electronics are disposed (directly) on a front side of the motor housing, in particular on a B-side of the motor shaft.

Here and in the following, “axial” or an “axial direction” is understood to mean in particular a direction parallel to (coaxial with) the axis of rotation of the electric motor, i.e., perpendicular to the front side of the motor housing. Accordingly, here and in the following, “radial” or a “radial direction” is understood to mean in particular a direction oriented perpendicular (transverse) to the axis of rotation of the electric motor along a radius of the electric motor. Here and in the following, “tangential” or a “tangential direction” is understood to mean in particular a direction along the circumference of the motor housing or the electric motor (circumferential direction, azimuthal direction), i.e., a direction perpendicular to the axial direction and the radial direction.

In one conceivable embodiment, the printed circuit board assembly has a recess through which an extension of the motor housing extends. The extension protrudes axially upward, for example, from the front side of the housing, with the printed circuit board assembly preferably being placed radially and/or tangentially in a form-locking manner onto the extension. This enables simplified alignment and/or positioning of the printed circuit board assembly during assembly of the electric machine.

The conjunction “and/or” is to be understood here and in the following in such a way that the features linked by this conjunction can be formed both together and as alternatives to one another.

The ground guidance bar is disposed on an edge of the printed circuit board assembly surrounding the recess. For example, the printed circuit board assembly is approximately annular, the recess forming the annular opening, and the ground guidance bar being disposed along an outer circumference of the recess. In particular, the ground guidance bar is thus disposed between the extension and the electronic components and/or the test points, so that it is ensured that the shortest discharge path runs from the motor housing or from the extension to the ground guidance bar.

In a preferred embodiment, the protective layer is embodied as a solder mask layer. In other words, a solder mask or solder mask material is applied to the circuit board assembly as an (arc) protection layer. In this embodiment, the surface of the printed circuit board assembly is thus substantially completely covered with a solder mask layer except for the ground guidance bar. This creates an especially simple and cost-effective protective layer.

A “solder mask” or a “solder mask layer” is understood here and below to mean in particular a protective layer on the printed circuit board which is intended and configured to prevent unwanted solder from adhering to certain areas of the printed circuit board.

Such a solder mask is made of a polymer material, for example, and conventionally covers all areas of the circuit board except those intended for soldering. The solder mask protects the circuit tracks and pads from oxidation and short circuits and makes it easier to apply solder only to the desired contact points.

In this embodiment, such a solder mask is used as a protective layer that substantially covers all metallic surfaces and components. The solder mask applied as a protective layer is applied in particular after a soldering process, so that the solder mask also covers contact points formed with solder on the printed circuit board assembly.

For example, a two-component, alkaline liquid photoimageable (LPI) solder mask, i.e. an LPI solder mask (also called solder resist), is used as a solder mask. The solder mask material is applied to the printed circuit board in liquid form and then hardened into a solid, protective layer through exposure to UV light and subsequent development. The solder mask is applied to the printed circuit board assembly using a flood screen and/or spray application process, for example.

The protective layer has a layer thickness that is sufficiently high to adequately reduce the probability of an electrical discharge from the motor housing to the printed circuit board assembly. What probability is considered adequate and how high the probability actually is is initially irrelevant. This depends, for example, on the protective layer material used as well as the distance of the printed circuit board assembly to the motor housing and the distance of the ground guidance bar to the motor housing. A suitable protective layer thickness can be determined from past machine data or from corresponding tests or trials, for example during a test measurement. The test measurement is carried out, for example, as part of a design or product validation for electrostatic discharge, in particular by using a DV ESD (Design Validation Electrostatic Discharge) or PV ESD (Product Validation Electrostatic Discharge) test. Different electric machines, coating materials, operating and environmental conditions, or application scenarios may require different coating thicknesses.

In one suitable embodiment, the protective layer has a layer thickness of greater than 15 μm (micrometers). Preferably, the protective layer has a layer thickness of between 20 μm and 25 μm. In other words, the protective layer has a minimum layer thickness of 15 μm, in particular between 20 μm and 25 μm.

In one possible embodiment, the protective layer or solder mask has a dielectric strength of 120 kV/mm (kilovolts per millimeter) and at least 10 μm for 500 V (volts). This results in an ESD dielectric strength of 3000 V for a layer thickness of 25 μm.

The distance between the exposed ground conductor and the motor housing or the extension is dimensioned as small as possible so that the impedance for the discharge path to the ground conductor is as low as possible. This advantageously increases the probability of the arc flashing over to the ground conductor. The distance is substantially determined by a (radial) air gap formed between the motor housing (or the extension) and the ground guidance bar. In one expedient embodiment, the air gap is dimensioned so as to be smaller than 2 mm, in particular between 0.9 mm and 1.5 mm.

Other features which are considered as characteristic for the invention are set forth in the appended claims.

Although the invention is illustrated and described herein as embodied in an electric machine for a motor vehicle, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a block diagram of an electric machine in the form of a brake module;

FIG. 2 is a diagrammatic, vertical-sectional view of a section of an electric motor drive of the electric machine; and

FIG. 3 is a perspective view of a section of the electric motor drive.

### DETAILED DESCRIPTION OF THE INVENTION

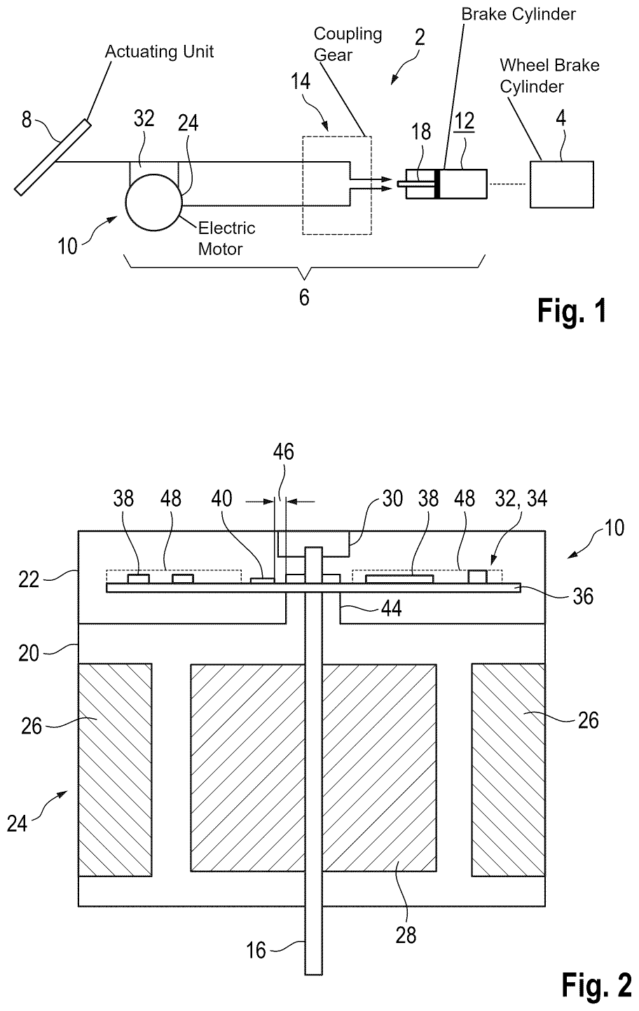

Referring now in detail to the figures of the drawings, in which analogous parts and quantities are provided with the same reference symbols, and first, particularly, to FIG. 1 thereof, there is seen a simplified block diagram of a braking system 2 for a motor vehicle. The braking system 2 is intended and configured to generate a hydraulic braking pressure at a wheel brake cylinder 4. The braking system 2 has a (brake) pressure generation unit as an electric machine 6 which can be actuated by an actuating unit 8, in particular by a brake pedal. When the actuating unit 8 is actuated, a brake pressure is generated at the wheel brake cylinder by the electric machine 6 in accordance with a driver's braking request.

Hereinafter, the electric machine 6 is also referred to as a pressure generation unit 6. The pressure generation unit 6 is embodied, for example, as a brake module, in particular as an Integrated Power Brake (IPB).

The pressure generation unit 6 has an electric drive 10 and a brake cylinder 12. Between the drive 10 and the brake cylinder 12 is disposed a coupling gear 14 which converts a rotary movement of a motor or drive shaft 16 (FIG. 2) into a translational movement of a piston 18 of the brake cylinder 12. The chamber of the brake cylinder 12 is connected, for example, to a hydraulic reservoir (not shown in detail).

The drive 10, described in greater detail below with reference to FIG. 2, has a metallic motor housing 20 and an electronics cover 22 placed on the front side thereof. An electric motor 24 with a stator 26 fixed to the housing and a rotor 28 coupled in a rotationally fixed manner to the motor shaft 16 is disposed in the motor housing 20. The motor shaft 16 is rotatably mounted in the motor housing 20. For example, the motor shaft 16 is mounted on a B-side by a bearing 30, which is disposed, for example, in a bearing seat of the electronics cover 22.

Between the B-side end face of the motor housing 20 and the electronics cover 22 placed thereon, an electronics compartment or electronics installation space is formed in which motor electronics 32, in particular in the form of control electronics or a control unit (Electronic Control Unit, ECU), are disposed. The motor electronics 32 receive a signal from the actuating unit 8 and control the electric motor 24 according to a desired brake pressure.

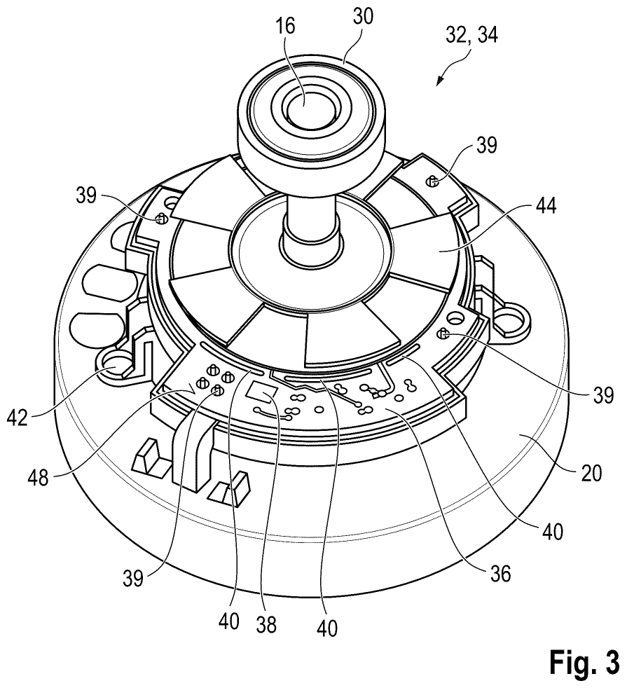

The motor electronics 32 have a printed circuit board assembly 34 with a printed circuit board 36 and with a number of electronic components 38 for carrying out the control functions. The components 38 are provided with reference numerals in the figures merely for the sake of example. The motor electronics 32 further include a number of test points 39 (FIG. 3) which are provided with reference numerals merely for the sake of example.

The printed circuit board assembly 34 further includes a number of conductor tracks for electrically contacting and interconnecting the electronic components 38. At least one of these conductor tracks is embodied as a ground guidance bar 40, i.e. as a conductor track connected to earth (ground, GND) or mass.

As can be seen in particular in the illustration of FIG. 3, the circuit board 36 is approximately circular in shape and has a central recess 42. An axially upwardly projecting extension 44 which is formed on the front side of the motor housing 20 preferably engages radially and/or tangentially in the recess 42 in a form-locking manner.

The at least one ground guidance bar 40 is disposed on an edge of the printed circuit board assembly 34 surrounding the recess 42. A radial distance 46 between the ground guidance bar 40 and the extension 44 is dimensioned so as to be less than 2 mm, in particular between 0.9 mm and 1.5 mm. As can be seen in particular in the illustration of FIG. 3, the ground guidance bar 40 is thus disposed between the extension 44 and the electronic components 38.

The printed circuit board assembly 34 further includes an applied electrically non-conductive or insulating protective layer 48 which substantially completely covers the surface of the printed circuit board assembly 34. The test points 39 and the at least one ground guidance bar 40 are exposed, i.e., not covered with the protective layer 48. The protective layer 48 covers the circuit board 36, the conductor tracks thereof, and the electronic components 38.

The protective layer 48 is embodied as a solder mask layer. The surface of the printed circuit board assembly 34 is thus substantially completely covered with a solder mask layer except for the ground guidance bar 40. The protective layer 48 has a layer thickness which is dimensioned so as to be large enough to reduce the probability of an electrical discharge from the motor housing 20 or extension 44 to the printed circuit board assembly 34. The protective layer 48 has, for example, a layer thickness of greater than 15 μm. Preferably, the protective layer 48 has a layer thickness of between 20 μm and 25 μm.

The at least one exposed ground guidance bar 40 is disposed on the printed circuit board assembly 34 or on the printed circuit board 36 in such a way that, in the event of an electrostatic charge on the motor housing 20, a discharge arc can form between the extension 44 and the ground guidance bar 40.

Due to the small distance 46 between the exposed ground guidance bar 40 and the extension 44, an impedance for the discharge path to the ground guidance bar 40 is especially low. Furthermore, the protective layer 48 increases an impedance for a discharge path to the printed circuit board assembly 34. This increases the probability that an arc that occurs will be formed on the ground guidance bar 40, thus protecting the electronic components 38 of the printed circuit board assembly 34.

The claimed invention is not limited to the exemplary embodiments described above. Rather, other variants of the invention can also be derived therefrom by a person skilled in the art within the scope of the disclosed claims without departing from the subject matter of the claimed invention. In particular, any and all individual features described in connection with the various exemplary embodiments can also be combined in other ways in the framework of the claims without departing from the subject matter of the claimed invention.

The following is a summary list of reference numerals and the corresponding structure used in the above description of the invention:
2 braking system
4 wheel brake cylinder
6 electric machine/pressure generation unit
8 actuating unit
10 drive
12 brake cylinder
14 coupling gear
16 motor shaft
18 piston
20 motor housing
22 electronics cover
24 electric motor
26 stator
28 rotor
30 bearing
32 motor electronics
34 PCB assembly
36 printed circuit board
38 electronic component
39 test point
40 ground guidance bar
42 recess
44 extension
46 distance
48 protective layer

1. An electric machine for a motor vehicle, the electric machine comprising:
an electric motor;
a metallic motor housing;
motor electronics being disposed on said motor housing and controlling said electric motor;
said motor electronics having a printed circuit board assembly with a ground guidance bar and with electronic components, said printed circuit board assembly having a surface;
an electrically non-conductive protective layer substantially completely covering said surface of said printed circuit board assembly except for said ground guidance bar; and
said ground guidance bar being disposed on said printed circuit board assembly to permit an arc discharge to form between said motor housing and said ground guidance bar in an event of an electrostatic charge on said motor housing.

2. The electric machine according to claim 1, wherein:
said printed circuit board assembly has a recess and an edge surrounding said recess;
said motor housing has an extension extending through said recess; and
said ground guidance bar is disposed on said edge of said printed circuit board assembly.

3. The electric machine according to claim 1, wherein said protective layer is a solder mask layer.

4. The electric machine according to claim 1, wherein said protective layer has a layer thickness greater than 15 μm.

5. The electric machine according to claim 1, wherein said protective layer has a layer thickness between 20 μm and 25 μm.

6. The electric machine according to claim 1, wherein said motor housing and said ground guidance bar are mutually spaced apart by a distance of less than 2 mm.

7. The electric machine according to claim 1, wherein said motor housing and said ground guidance bar are mutually spaced apart by a distance of between 0.9 mm and 1.5 mm.
